(19) United States
(12) Patent Application Publication
(10) Pub. No.: US 2025/0260335 A1
(43) Pub. Date: Aug. 14, 2025

(54) POWER CONVERSION DEVICE

(71) Applicant: HONDA MOTOR CO., LTD., Tokyo (JP)

(72) Inventor: Shogo Ito, Wako-shi (JP)

(21) Appl. No.: 19/044,677

(22) Filed: Feb. 4, 2025

(30) Foreign Application Priority Data
Feb. 8, 2024 (JP) 2024-017561

(51) Int. Cl. H02M 7/00; H05K 1/18

(52) U.S. Cl. CPC H02M 7/003; H05K 1/18; H05K 2201/10015; H05K 2201/10272

(57) ABSTRACT

A power conversion device includes a power conversion unit that converts three phase alternating-current power supplied from a three phase alternating-current power source into direct-current power, a first busbar connected to a first phase terminal of the power conversion unit and provided to an insulating substrate, a second busbar connected to second phase terminal of the power conversion unit and provided to the insulating substrate, and a third busbar connected to third phase terminal of the power conversion unit and provided to the insulating substrate, a first insulating layer is positioned on the second busbar, and the first busbar and the third busbar are positioned on the first insulating layer.

### CROSS-REFERENCE TO RELATED APPLICATIONS

This application is based upon and claims the benefit of priority from Japanese Patent Application No. 2024-017561 filed on Feb. 8, 2024, the contents of which are incorporated herein by reference.

### BACKGROUND OF THE INVENTION

### Field of the Invention

The present disclosure relates to a power conversion device.

### Description of the Related Art

In recent years, efforts toward realization of low-carbon or decarbonized society have been activated, and research and development have been conducted on power conversion devices for reducing CO₂ emission and improving energy efficiencies also in moving objects including aircrafts.

JP 2021-129406 A discloses a power conversion device interposed between a battery and an alternating-current motor. The power conversion unit converts the direct-current power supplied from the battery into three-phase alternating-current power and outputs the three-phase alternating-current power to the three-phase alternating-current motor. The power conversion device includes a plurality of power cards (switching elements), a plurality of output busbars, and a plurality of external connection terminals. The U-phase power card is connected to the U-phase external connection terminal via the U-phase output busbar. Similarly, the V-phase power card is connected to the V-phase external connection terminal via the V-phase output busbar, and the W-phase power card is connected to the W-phase external connection terminal via the W-phase output busbar. Adjacent two output busbars are spaced from each other for insulation.

### SUMMARY OF THE INVENTION

A better power conversion device is desired.

The present invention has the object of solving the aforementioned problem.

An aspect of the present disclosure is to provide a power conversion device including a power conversion unit configured to convert three-phase alternating-current power, which is supplied from a three-phase alternating-current power source, into direct-current power; an insulating substrate formed of an insulating material; a first busbar connected to a first phase terminal of the power conversion unit, the insulating substrate being provided with the first busbar; a second busbar connected to a second phase terminal of the power conversion unit, the insulating substrate being provided with the second busbar; and a third busbar connected to a third phase terminal of the power conversion unit, the insulating substrate being provided with the third busbar, wherein the insulating substrate includes a plurality of insulating layers, a first insulating layer of the plurality of insulating layers is positioned on the second busbar, the first busbar and the third busbar are positioned on the first insulating layer, and the first busbar, the second busbar, and the third busbar are mutually insulated by the insulating material forming the insulating substrate.

According to the present invention, a favorable power conversion device can be provided.

The above and other objects, features and advantages of the present invention will become more apparent from the following description when taken in conjunction with the accompanying drawings in which a preferred embodiment of the present invention is shown by way of illustrative example.

### BRIEF DESCRIPTION OF THE DRAWINGS

FIG. 1 is a schematic diagram of an aircraft;

FIG. 2 is a circuit diagram of the power supply device;

FIG. 3 is a perspective view of a Power Control Unit (PCU);

FIG. 4 is a perspective view of a power conversion unit;

FIG. 5 is a perspective view of the power conversion unit and a cooler;

FIG. 6 is a perspective view of five busbars and the power conversion unit;

FIG. 7 is a side view of the five busbars and the power conversion unit;

FIG. 8 is a plan view of a first conductive layer; and

FIG. 9 is a plan view of a second conductive layer.

### DETAILED DESCRIPTION OF THE INVENTION

It is desirable that a power conversion device provided, for example, in a moving object be small. Therefore, it is preferable that two busbars are disposed as close as possible in the power conversion device. The power conversion device according to the embodiment described below can reliably insulate a plurality of busbars from each other while shortening the distance therebetween.

A power conversion device 10 according to one embodiment will be described with reference to the drawings. In the present embodiment, a case where the power conversion device 10 is a power control unit will be described as an example, but the present invention is not limited thereto. The power control unit 10 is mounted on a moving object. In the present embodiment, a case where the moving object is an aircraft 12 will be described as an example, but the present invention is not limited thereto.

### 1 Configuration of Aircraft 12

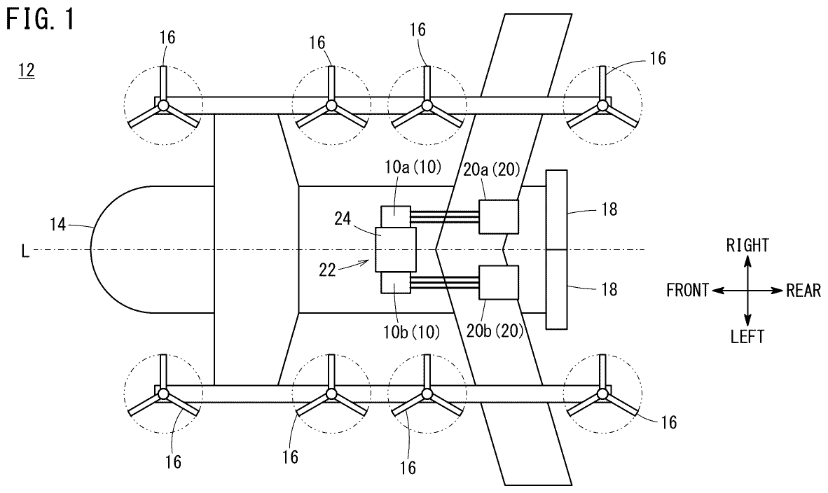

FIG. 1 is a schematic diagram of an aircraft 12. The aircraft 12 according to the present embodiment is an electric vertical take-off and landing (eVTOL) aircraft. In the aircraft 12, electric motors drive rotors. The aircraft 12 generates a vertical thrust and a horizontal thrust by the rotors.

The aircraft 12 has an airframe 14. The aircraft 12 has eight VTOL rotors 16. The VTOL rotors 16 generate an upwardly directed thrust with respect to the airframe 14. The aircraft 12 includes two cruise rotors 18. The cruise rotors 18 generate a forwardly directed thrust with respect to the airframe 14.

The VTOL rotors 16 and the cruise rotors 18 are driven by electric motors (not shown). The aircraft 12 includes a generator 20 and a battery (not shown) as power sources of the electric motors. The electrical power supplied by the generator 20 is supplied to electric motors. The electrical power supplied by the generator 20 is stored in a battery (capacitor). In the case that the electrical power generated by the generator 20 is insufficient with respect to the required amount of electrical power, the electrical power stored in the battery is supplied to the electric motors.

### 2 Configuration of Power Supply Device 22

The aircraft 12 includes a power supply device 22. The power supply device 22 includes the generator 20, a power control unit 10, and a main junction box 24. Hereinafter, the power control unit 10 may be referred to as a PCU 10. The main junction box 24 may be referred to as an MJB 24.

Two generators 20 are provided for the power supply device 22. One of the two generators 20 is a first power generator 20a, and the other of the two generators 20 is a second power generator 20b. The first power generator 20a is disposed on the right side of the center line L in the lateral direction of the airframe 14 of the aircraft 12, and the second power generator 20b is disposed on the left side of the center line L.

The power supply device 22 has two PCUs 10. One of the two PCUs 10 is a first PCU 10a, and the other of the two PCUs 10 is a second PCU 10b. The MJB 24 is disposed about the center line L of the airframe 14. The first PCU 10a is attached to the right side surface of the MJB 24, and the second PCU 10b is attached to the left side surface of the MJB 24.

The three-phase alternating-current electrical power generated by the first power generator 20a is supplied to the first PCU 10a. The first PCU 10a converts the three-phase alternating-current electrical power supplied from the first power generator 20a into direct-current electrical power. The converted direct-current electrical power is supplied to the MJB 24.

The three-phase alternating-current electrical power generated by the second power generator 20b is supplied to the second PCU 10b. The second PCU 10b converts the three-phase alternating-current electrical power supplied from the second power generator 20b into direct-current electrical power. The converted direct-current electrical power is supplied to the MJB 24.

### 3 Configuration of Power Supply Device 22

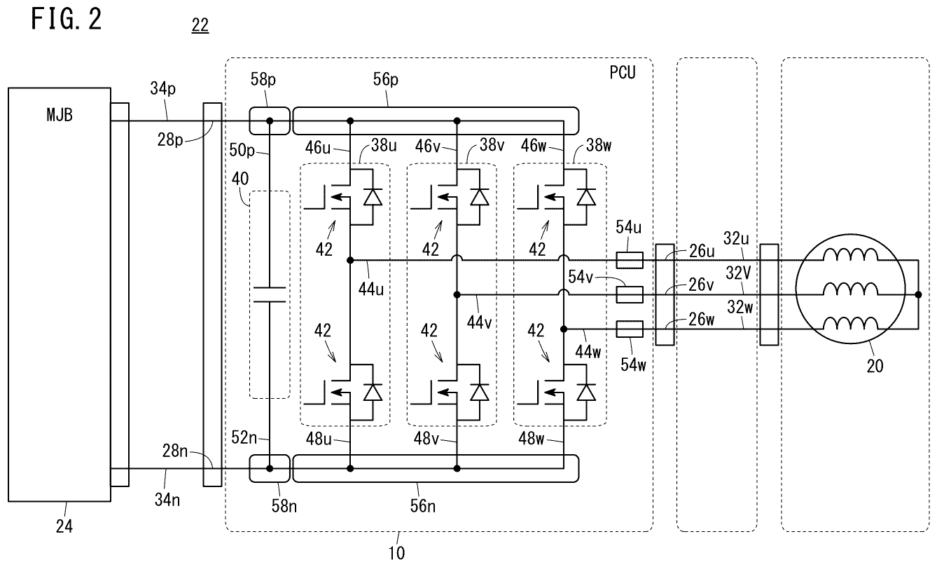

FIG. 2 is a circuit diagram of the power supply device 22. FIG. 2 illustrates a circuit including the power generator 20 disposed on one of the left and right sides, the PCU 10 disposed on one of the left and right sides, and a MJB 24. The circuit of the PCU 10 will be described below.

The PCU 10 includes three external connection terminals 26u, 26v, 26w, and two external connection terminals 28p, 28n. The three external connection terminals 26u, 26v, 26w, and the two external connection terminals 28p, 28n are attached to a casing (not shown).

The external connection terminal 26u is connected to the power generator 20 via a U-phase wire 32u. The external connection terminal 26v is connected to the power generator 20 via a V-phase wire 32v. The external connection terminal 26w is connected to the power generator 20 via a W-phase wire 32w. The external connection terminal 28p is connected to the MJB 24 via a positive electrode line 34p. The external connection terminal 28n is connected to the MJB 24 via the negative electrode line 34n.

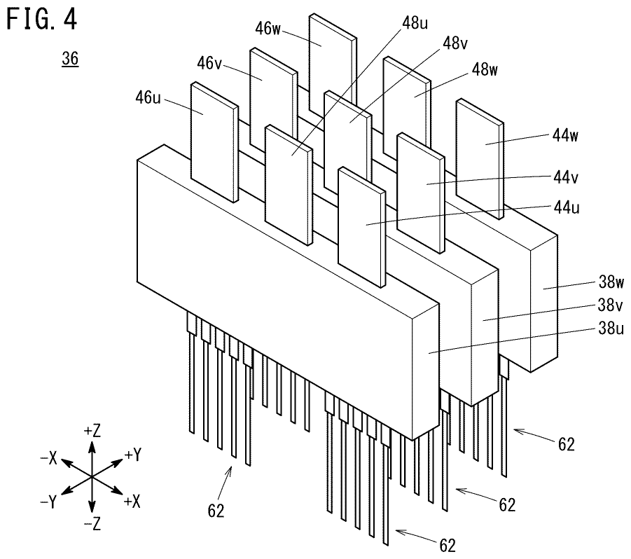

The PCU 10 includes a U-phase power module 38u, a V-phase power module 38v, a W-phase power module 38w, and a smoothing capacitor 40. As shown in FIG. 4, the three power modules (38u, 38v, 38w) are also collectively referred to as a power conversion unit 36. The U-phase power module 38u includes two power devices 42, the U-phase terminal (first phase terminal) 44u, the positive terminal (first direct-current terminal) 46u, and the negative terminal (second direct-current terminal) 48u. The V-phase power module 38v includes two power devices 42, the V-phase terminal (second phase terminal) 44v, the positive terminal (first direct-current terminal) 46v, and the negative terminal (second direct-current terminal) 48v. The W-phase power module 38w includes two power devices 42, the W-phase terminal (third phase terminal) 44w, the positive terminal (first direct-current terminal) 46w, and the negative terminal (second direct-current terminal) 48w. Each power device 42 includes a switching element such as a MOSFET and a diode. The smoothing capacitor 40 includes a positive terminal 50p and a negative terminal 52n.

In the U-phase power module 38u, one of the two power devices 42 is connected to the positive terminal 46u and the U-phase terminal 44u. In the U-phase power module 38u, the other of the two power devices 42 is connected to the negative terminal 48u and the U-phase terminal 44u.

In the V-phase power module 38v, one of the two power devices 42 is connected to the positive terminal 46v and the V-phase terminal 44v. In the V-phase power module 38v, the other of the two power devices 42 is connected to the negative terminal 48v and the V-phase terminal 44v.

In the W-phase power module 38w, one of the two power devices 42 is connected to the positive terminal 46w and the W-phase terminal 44w. In the W-phase power module 38w, the other of the two power devices 42 is connected to the negative terminal 48w and the W-phase terminal 44w.

The U-phase terminal 44u of the U-phase power module 38u is connected to the external connection terminal 26u of the PCU 10 via the U-phase busbar (first busbar) 54u. The V-phase terminal 44v of the V-phase power module 38v is connected to the external connection terminal 26v of the PCU 10 via the V-phase busbar (second busbar) 54v. The W-phase terminals 44w of the W-phase power module 38w is connected to the external connection terminal 26w of the PCU 10 via the W-phase busbar (third busbar) 54w.

The positive terminal 46u of the U-phase power module 38u, the positive terminal 46v of the V-phase power module 38v, and the positive terminal 46w of the W-phase power module 38w are connected respectively to the external connection terminal 28p of the PCU 10 via the first positive busbar (fourth busbar) 56p and the second positive busbar 58p. The positive terminal 50p of the smoothing capacitor 40 is connected to the external connection terminal 28p of the PCU 10 via the second positive busbar 58p.

The negative terminal 48u of the U-phase power module 38u, the negative terminal 48v of the V-phase power module 38v, and the negative terminal 48w of the W-phase power module 38w are respectively connected to the external connection terminal 28n of the PCU 10 via the first negative busbar (fifth busbar) 56n and the second negative busbar 58n. The negative electrode terminal 52n of the smoothing capacitor 40 is connected to the external connection terminal 28n of the PCU 10 via the second negative busbar 58n.

### 4 Configuration of PCU 10

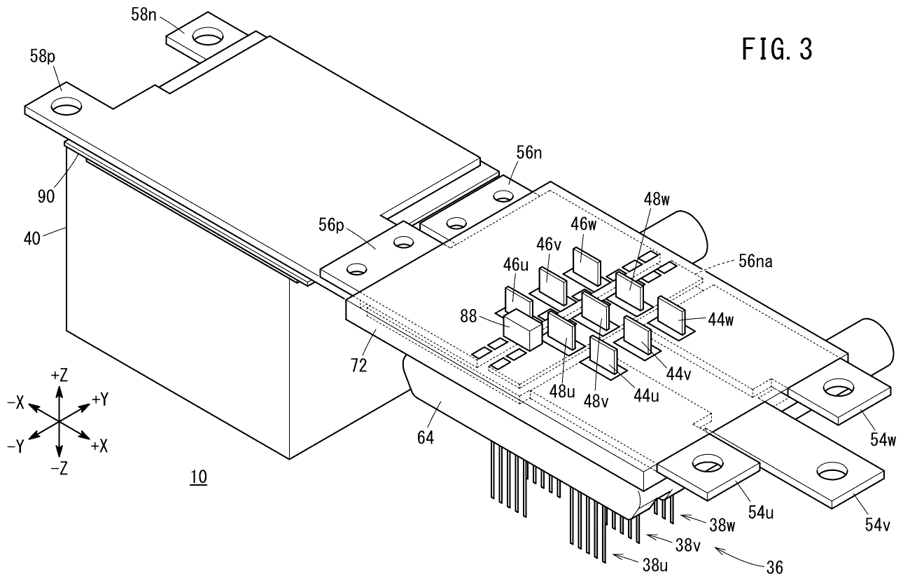

FIG. 3 is a perspective view of the PCU 10. FIG. 3 shows the PCU 10 with the external connection terminals 26u, 26v, 26w, 28p, 28n and the casing removed. In FIG. 3, arrows indicating the X direction, the Y direction, and the Z direction are shown. The X direction, the Y direction, and the Z direction are orthogonal to each other. One of the X directions is defined as a +X direction, and the other is defined as a −X direction. The same applies to the Y direction and the Z direction.

As described above, the PCU 10 includes the plurality of power modules (38u, 38v, 38w), the smoothing capacitor 40, and the plurality of busbars (54u, 54v, 54w, 56p, 56n, 58p, 58n). The PCU 10 further comprises a cooler 64.

FIG. 4 is a perspective view of the power conversion unit 36. Each of the U-phase power module 38u, the V-phase power module 38v, and the W-phase power module 38w has a shape of a flat plate extending in the X direction and the Z direction. The U-phase power module 38u, the V-phase power module 38v, and the W-phase power module 38w are arranged along the Y direction.

As described above, the U-phase power module 38u includes the two power devices 42 (FIG. 2). The two power devices 42 are sealed with an insulating material containing resin or the like. Thus, the two power devices 42 are integrated. The U-phase power module 38u includes the U-phase terminal 44u, the positive terminal 46u, the negative terminal 48u, and a plurality of signal terminals 62. Each of the U-phase terminal 44u, the positive terminal 46u, and the negative terminal 48u extends from the U-phase power module 38u in the +Z direction. The plurality of signal terminals 62 extend from the U-phase power module 38u in the −Z direction. Each of the signal terminals 62 is connected to an unillustrated driver circuit. The driver circuit amplifies signals output from an unillustrated controller. The driver circuit supplies amplified drive signals to the signal terminals 62. The V-phase power module 38v and the W-phase power module 38w are configured in the same manner as the U-phase power module 38u. Therefore, the descriptions thereof are omitted here.

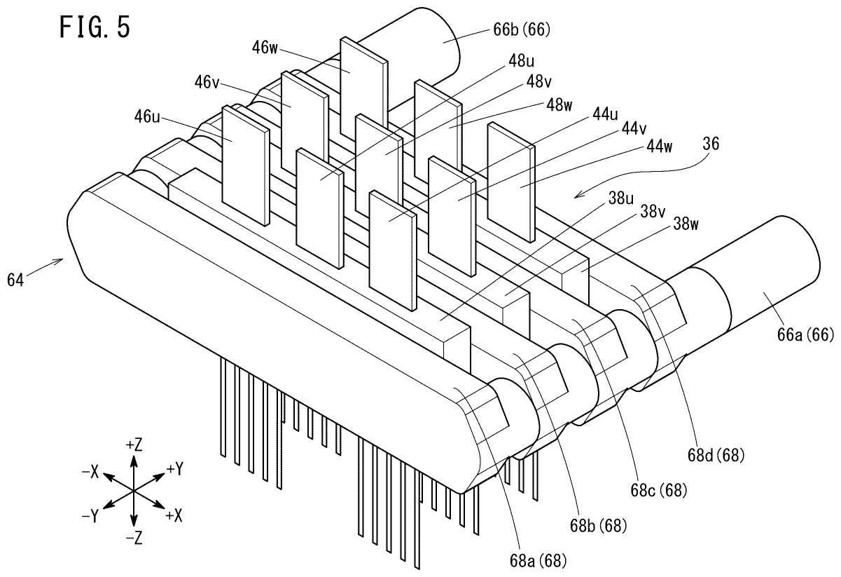

FIG. 5 is a perspective view of the power conversion unit 36 and the cooler 64. The cooler 64 includes two pipe sections 66 and four pipe sections 68. The two pipe sections 66 extend along the Y direction. The four pipe sections 68 extend along the X direction. The four pipe sections 68 extend between the two pipe sections 66. One end of each pipe section 68 is connected to one pipe section 66a of the two pipe sections 66. The other end of each pipe section 68 is connected to the other pipe section 66b of the two pipe sections 66. Thus, the two pipe sections 66 communicate with each other via the four pipe sections 68. Each of the two pipe sections 66 communicates with a pump (not shown).

The pipe section 68a of the four pipe sections 68 is in contact with an outer wall surface of the U-phase power module 38u facing in the −Y direction. The pipe section 68b of the four pipe sections 68 is in contact with an outer wall surface of the U-phase power module 38u facing in the +Y direction and also with an outer wall surface of the V-phase power module 38v facing in the −Y direction. The pipe section 68c of the four pipe sections 68 is in contact with an outer wall surface of the V-phase power module 38v facing in the +Y direction and also with an outer wall surface of the W-phase power module 38w facing in the −Y direction. The pipe section 68d of the four pipe sections 68 is in contact with the outer wall surface of the W-phase power module 38w facing in the +Y direction.

A cooling medium is caused to flow inside the cooler 64. For example, the cooling medium is discharged from the pump to the pipe section 66a, and is supplied from the pipe section 66a to each of the four pipe sections 68. Further, the cooling medium is discharged from the four pipe sections 68 to the pipe section 66b and is cooled by an unillustrated radiator or the like. The cooling medium having been cooled returns to the pump. The cooling medium absorbs heat of the plurality of power modules (38u, 38v, 38w) and radiates heat in the radiator. Thus, the plurality of power modules (38u, 38v, 38w) are cooled.

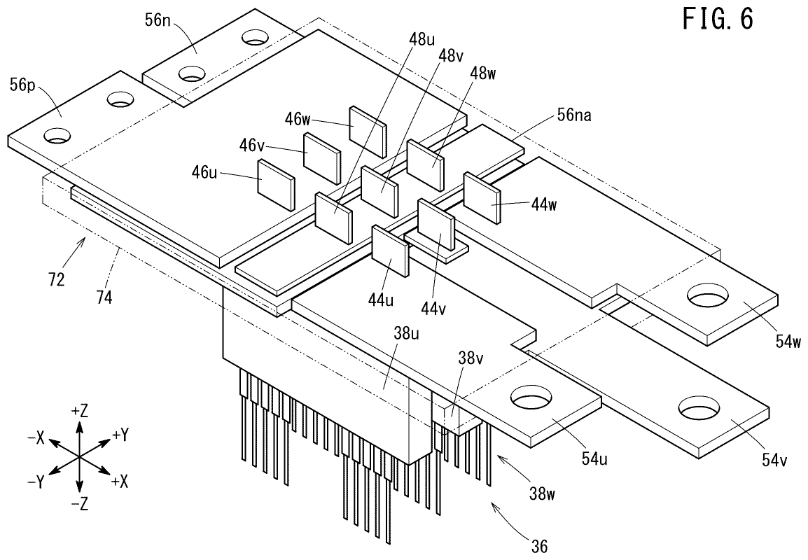

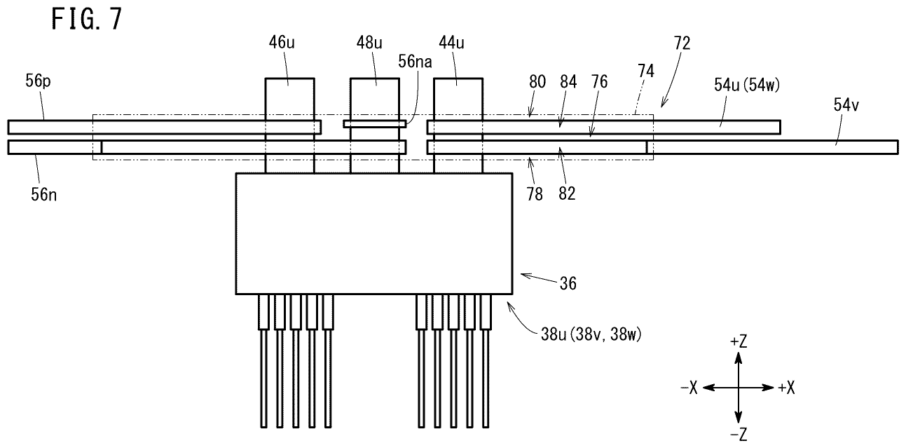

FIG. 6 is a perspective view of five busbars (54u, 54v, 54w, 56p, 56n) and the power conversion unit 36. FIG. 7 is a side view of the five busbars (54u, 54v, 54w, 56p, 56n) and the power conversion unit 36. In FIG. 7, the V-phase power module 38v and the W-phase power module 38w are hidden behind the U-phase power module 38u. Therefore, in FIG. 7, the reference numerals relating to the V-phase power module 38v and the W-phase power module 38w are shown in parentheses. Similarly, in FIG. 7, the W-phase busbar 54w is hidden behind the U-phase busbar 54u. Therefore, in FIG. 7, the reference numeral relating to the W-phase busbar 54w is shown in parentheses.

As shown in FIG. 6, the U-phase busbar 54u, the V-phase busbar 54v, the W-phase busbar 54w, the first positive busbar 56p, and the first negative busbar 56n are disposed on a common insulating substrate 74. The U-phase busbar 54u is partially sealed by the insulating material forming the insulating substrate 74. Each of the V-phase busbar 54v, the W-phase busbar 54w, the first positive busbar 56p, and the first negative busbar 56n is also partially sealed in the same manner as the U-phase busbar 54u. The five busbars (54u, 54v, 54w, 56p, 56n) and the insulating substrate 74 form an integrated busbar board 72.

The busbar board 72 includes a plurality of insulating layers stacked along the Z direction. For example, as shown in FIG. 7, the busbar board 72 includes a first insulating layer 76, a second insulating layer 78, and a third insulating layer 80. The first insulating layer 76 is arranged between the second insulating layer 78 and the third insulating layer 80. In addition, the busbar board 72 includes a first conductive layer 82 and a second conductive layer 84. The first conductive layer 82 includes the V-phase busbar 54v and the first negative busbar 56n. The second conductive layer 84 includes the U-phase busbar 54u, the W-phase busbar 54w, the first positive busbar 56p, and a supplementary negative busbar 56na. The first negative busbar 56n of the first conductive layer 82 and the supplementary negative busbar 56na of the second conductive layer 84 are electrically connected to each other by a through hole or the like (not shown).

Each of the busbars (54u, 54v, 54w, 56p, 56n, 56na) may be formed of a metallic film (e.g., a copper film). In this case, the insulating substrate 74 may be a printed circuit board. Each of the busbars (54u, 54v, 54w, 56p, 56n, 56na) may be made of rolled metal (such as rolled copper). In this case, the metal is embedded in the insulating material.

The first conductive layer 82 is formed between the second insulating layer 78 and the first insulating layer 76. The second conductive layer 84 is formed between the first insulating layer 76 and the third insulating layer 80. In other words, the first insulating layer 76 is formed on the V-phase busbar 54v and the first negative busbar 56n. In addition, the U-phase busbar 54u, the W-phase busbar 54w, the first positive busbar 56p, and the supplementary negative busbar 56na are positioned on the first insulating layer 76. In other words, the first insulating layer 76 is interposed between the first conductive layer 82 and the second conductive layer 84.

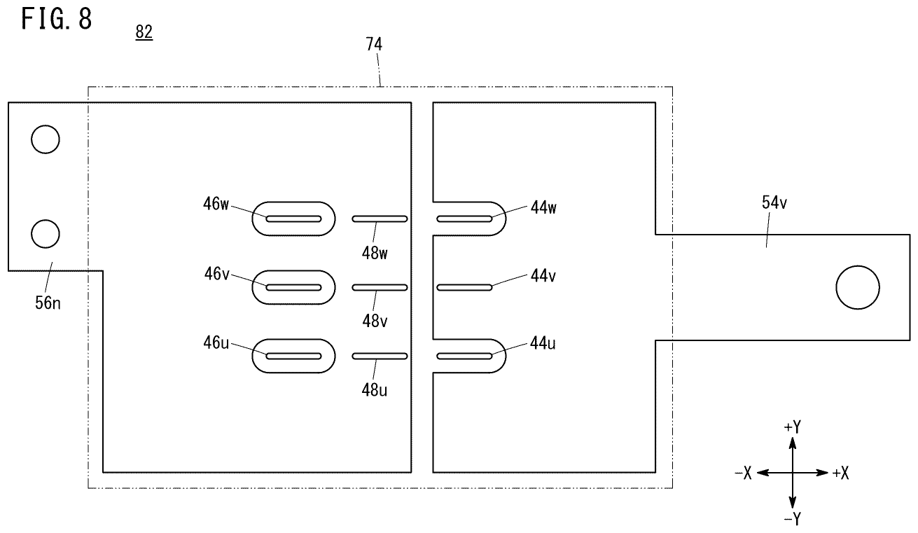

FIG. 8 is a plan view of a first conductive layer 82. As shown in FIG. 8, in the first conductive layer 82, the V-phase busbar 54v and the first negative busbar 56n are arranged along the X direction. The V-phase busbar 54v and the first negative busbar 56n are separated from each other. An insulating material forming the insulating substrate 74 is interposed between the V-phase busbar 54v and the first negative busbar 56n.

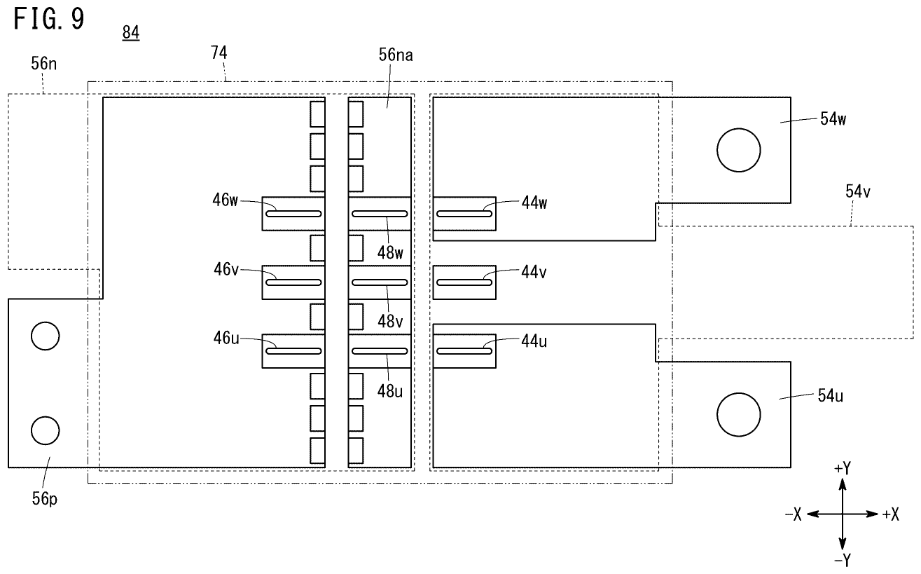

FIG. 9 is a plan view of the second conductive layer 84. As shown in FIG. 9, in the second conductive layer 84, the U-phase busbar 54u and the W-phase busbar 54w are arranged along the Y direction. The U-phase busbar 54u, the supplementary negative busbar 56na, and the first positive busbar 56p are arranged along the X direction. The W-phase busbar 54w, the supplementary negative busbar 56na, and the first positive busbar 56p are arranged along the X direction. The U-phase busbar 54u, the W-phase busbar 54w, the supplementary negative busbar 56na, and the first positive busbar 56p are separated from each other. The insulating material forming the insulating substrate 74 is interposed between each of the U-phase busbar 54u, the W-phase busbar 54w, the supplementary negative busbar 56na, and the first positive busbar 56p.

When viewed in the stacking direction, the U-phase busbar 54u and the V-phase busbar 54v overlap each other at least partially. In the present embodiment, as shown in FIG. 9, the U-phase busbar 54u and the V-phase busbar 54v overlap each other at least partially when viewed in the Z direction.

When viewed in the stacking direction, the W-phase busbar 54w and the V-phase busbar 54v overlap each other at least partially. In the present embodiment, as shown in FIG. 9, the W-phase busbar 54w and the V-phase busbar 54v overlap each other at least partially when viewed in the Z direction.

When viewed in the stacking direction, the first positive busbar 56p and the first negative busbar 56n overlap each other at least partially. In the present embodiment, as shown in FIG. 9, the first positive busbar 56p and the first negative busbar 56n overlap each other at least partially when viewed in the Z direction.

As shown in FIG. 3, each of the U-phase terminal 44u, the positive terminal 46u, and the negative terminal 48u of the U-phase power module 38u extends through the busbar board 72 and protrudes in the +Z direction. At the protruded portion, the U-phase terminal 44u is joined, by soldering or the like, to a portion of the U-phase busbar 54u exposed in the +Z direction. At the protruding portion, the positive terminal 46u is joined, by soldering or the like, to a portion of the first positive busbar 56p exposed in the +Z direction. At the protruding portion, the negative terminal 48u is joined, by soldering or the like, to a portion of the supplementary negative busbars 56na exposed in the +Z direction.

Similarly to the U-phase power module 38u, each of the V-phase terminal 44v, the positive terminal 46v, and the negative terminal 48v of the V-phase power module 38v extends through the busbar board 72 and protrudes in the +Z direction. At the protruded portion, the V-phase terminal 44v is joined, by soldering or the like, to a portion of the V-phase busbar 54v exposed in the +Z direction. At the protruding portion, the positive terminal 46v is joined, by soldering or the like, to a portion of the first positive busbar 56p exposed in the +Z direction. At the protruding portion, the negative terminal 48v is joined, by soldering or the like, to a portion of the supplementary negative busbars 56na exposed in the +Z direction.

Similarly to the U-phase power module 38u, each of the W-phase terminal 44w, the positive terminal 46w, and the negative terminal 48w of the W-phase power module 38w extends through the busbar board 72 and protrudes in the +Z direction. At the protruded portion, the W-phase terminal 44w is joined, by soldering or the like, to a portion of the W-phase busbar 54w exposed in the +Z direction. At the protruding portion, the positive terminal 46w is joined, by soldering or the like, to a portion of the first positive busbar 56p exposed in the +Z direction. At the protruding portion, the negative terminal 48w is joined, by soldering or the like, to a portion of the supplementary negative busbars 56na exposed in the +Z direction.

The end of the U-phase busbar 54u on the +X direction side is connected to the external connection terminal 26u (FIG. 2). The end of the V-phase busbar 54v on the +X direction side is connected to the external connection terminals 26v (FIG. 2). The end of the W-phase busbar 54w on the +X direction side is connected to the external connection terminals 26w (FIG. 2). The end of the first positive busbar 56p on the −X direction side is connected to the second positive busbar 58p. The end of the first negative busbar 56n on the −X direction side is connected to the second negative busbar 58n.

As shown in FIG. 3, the PCU 10 includes a snubber capacitor 88. The snubber capacitor 88 is disposed on the outer wall surface of the busbar board 72 on the +Z direction side. One end of the snubber capacitor 88 is joined, by soldering or the like, to a portion of the first positive busbar 56p exposed in the +Z direction. The other end of the snubber capacitor 88 is joined, by soldering or the like, to a portion of the supplementary negative busbar 56na exposed in the +Z direction.

As shown in FIG. 3, the second positive busbar 58p and the second negative busbar 58n are stacked along the Z direction. The insulating body 90 is interposed between the second positive busbar 58p and the second negative busbar 58n. The second positive busbar 58p is connected to the positive electrode terminal 50p (FIG. 2) of the smoothing capacitor 40. The second positive busbar 58p is connected to the external connection terminal 28p (FIG. 2). The second negative busbar 58n is connected to the negative electrode terminal 52n (FIG. 2) of the smoothing capacitor 40. The second negative busbar 58n is connected to the external connection terminal 28n (FIG. 2).

In the present embodiment, the first insulating layer 76 is positioned on the V-phase busbar 54v, and the U-phase busbar 54u and the W-phase busbar 54w are positioned on the first insulating layer 76. Instead, the first insulating layer 76 may be positioned on the U-phase busbar 54u, and the V-phase busbar 54v and the W-phase busbar 54w may be positioned on the first insulating layer 76. Further, the first insulating layer 76 may be positioned on the W-phase busbar 54w, and the U-phase busbar 54u and the V-phase busbar 54v may be positioned on the first insulating layer 76. In these embodiments, two of the three busbars (the U-phase busbar 54u, the V-phase busbar 54v, and the W-phase busbar 54w) are arranged in the +Z direction, and one of the three busbars is arranged in the −Z direction. Instead, one of the three busbars (the U-phase busbar 54u, the V-phase busbar 54v, and the W-phase busbar 54w) may be arranged in the +Z direction, and two of the three busbars may be arranged in the −Z direction.

In the present embodiment, the first insulating layer 76 is formed on the first negative busbar 56n, and the first positive busbar 56p is positioned on the first insulating layer 76. Instead, the first insulating layer 76 may be formed on the first positive busbar 56p, and the first negative busbar 56n may be positioned on the first insulating layer 76.

According to the present embodiment, the busbars (54u, 54v, 54w, 56p, 56n) are insulated from each other by the insulating material forming the insulating substrate 74, and thus the distances between the busbars can be made shorter than in the case where spaces are provided between the busbars. Therefore, the power conversion device 10 can be downsized.

According to the present embodiment, the busbars (54u, 54v, 54w, 56p, 56n) disposed in the different layers overlap each other when viewed in the stacking direction. In the case of arranging two busbars in an area, the size of each busbar can be larger if the two busbars overlap each other than if the two busbars do not overlap each other. That is, according to the present embodiment, since each busbar can be increased in size, the heat dissipation of the busbars can be improved. On the other hand, in the case of arranging two busbars of the same size on one substrate, the size of the substrate can be smaller if the two busbars overlap each other than if the two busbars do not overlap each other. That is, according to the present embodiment, the substrate can be made small, and thus the space around the substrate can be effectively used.

According to the present embodiment, the three busbars (54u, 54v, 54w) and the two busbars (56p, 56n) are integrated. Therefore, easy assembling of the PCU 10 can be achieved.

Since the snubber capacitor 88 is disposed in the vicinity of the power conversion unit 36, the present embodiment can elicit high switching performance of the power conversion unit 36.

### 5 Supplementary Note

In relation to the above-described embodiment, the following Supplementary Notes are further disclosed.

### Supplementary Note 1

The power conversion device (10) according to the present disclosure includes the power conversion unit (36) configured to convert three-phase alternating-current power, which is supplied from a three-phase alternating-current power source (20), into direct-current power; the insulating substrate (74) formed of an insulating material; the first busbar (54u) connected to the first phase terminal (44u) of the power conversion unit, the insulating substrate being provided with the first busbar; the second busbar (54v) connected to the second phase terminal (44v) of the power conversion unit, the insulating substrate being provided with the second busbar; and the third busbar (54w) connected to the third phase terminal (44w) of the power conversion unit, the insulating substrate being provided with the third busbar, wherein the insulating substrate includes the plurality of insulating layers (76, 78, 80), the first insulating layer (76) of the plurality of insulating layers is positioned on the second busbar, the first busbar and the third busbar are positioned on the first insulating layer, and the first busbar, the second busbar, and the third busbar are mutually insulated by the insulating material forming the insulating substrate.

In accordance with such a configuration of Supplementary Note 1, since the busbars are insulated from each other by the insulating material forming the insulating substrate, the distances between the busbars can be made shorter than in the case where the busbars are insulated by being spaced from each other. Therefore, the power conversion device can be downsized.

### Supplementary Note 2

In the power conversion device according to Supplementary Note 1, the first busbar and the second busbar may overlap each other at least partially when viewed in the stacking direction of the insulating layers.

### Supplementary Note 3

In the power conversion device according to Supplementary Note 2, the third busbar and the second busbar may overlap each other at least partially when viewed in the stacking direction of the insulating layers.

According to the configurations of Supplementary Notes 2 and 3, the busbars in different layers overlap each other when viewed in the stacking direction. In the case of arranging two busbars in one area, the size of each busbar can be larger if the two busbars overlap each other than if the two busbars do not overlap each other. That is, according to the present embodiment, since each busbar can be increased in size, the heat dissipation of the busbars can be improved. On the other hand, in the case of arranging two busbars of the same size in one substrate, the size of the substrate can be smaller if the two busbars overlap each other than if the two busbars do not overlap each other. That is, according to the present embodiment, the substrate can be made small, and thus the space around the substrate can be effectively used.

### Supplementary Note 4

In the power conversion device according to any one of Supplementary Notes 1 to 3, each of the first phase terminal, the second phase terminal, and the third phase terminal may extend in the stacking direction of the insulating layers and pass through the insulating substrate.

### Supplementary Note 5

The power conversion device according to Supplementary Note 1 may further include the fourth busbar (56p) connected to the first direct-current terminal (46u, 46v, 46w) of the power conversion unit, the insulating substrate being provided with the fourth busbar, and the fifth busbar (56n) connected to the second direct-current terminal (48u, 48v, 48w) of the power conversion unit, the insulating substrate being provided with the fifth busbar, wherein the first insulating layer may be positioned on the second busbar and the fifth busbar, the first busbar, the third busbar and the fourth busbar are positioned on the first insulating layer, and the first busbar, the second busbar, the third busbar, the fourth busbar, and the fifth busbar are mutually insulated by the insulating material forming the insulating substrate.

According to the configuration of Supplementary Note 5, the first to third busbars and the fourth and fifth busbars are integrated. Therefore, the assemblability of the power conversion device can be improved.

### Supplementary Note 6

In the power conversion device according to Supplementary Note 5, each of the first phase terminal, the second phase terminal, the third phase terminal, the first direct-current terminal, and the second direct-current terminal may extend in a stacking direction of the insulating layers and pass through the insulating substrate.

### Supplementary Note 7

The power conversion device according to Supplementary Note 5 or 6 may further include the snubber capacitor (88) having one end connected to the fourth busbar and the other end connected to the fifth busbar.

In accordance with the configuration of Supplementary Note 7, since the snubber capacitor is arranged in the vicinity of the power conversion unit, the present embodiment can elicit high switching performance of the power conversion unit.

### Supplementary Note 8

In the power conversion device according to any one of Supplementary Notes 1 to 7, the insulating substrate may be a printed substrate.

According to the configuration of Supplementary Note 8, such the busbars are thinned, and thus the power conversion device can be further downsized.

Although concerning the present disclosure, a detailed description thereof has been presented above, the present disclosure is not necessarily limited to the individual embodiments described above. These embodiments may be subjected to various additions, substitutions, modifications, partial deletions and the like, within a range that does not deviate from the essence and gist of the present disclosure, or the spirit of the present disclosure as derived from the contents described in the claims and equivalents thereof. Further, the embodiments can also be implemented together in combination. For example, in the above-described embodiments, the order of each of the operations and the order of each of the processes are illustrated as examples, and the present invention is not necessarily limited to these features. The same also applies to cases in which numerical values or mathematical expressions are used in the description of the aforementioned embodiments.

1. A power conversion device comprising: a power conversion unit configured to convert three-phase alternating-current power, which is supplied from a three-phase alternating-current power source, into direct-current power;
an insulating substrate formed of an insulating material;
a first busbar connected to a first phase terminal of the power conversion unit, the insulating substrate being provided with the first busbar;
a second busbar connected to a second phase terminal of the power conversion unit, the insulating substrate being provided with the second busbar; and
a third busbar connected to a third phase terminal of the power conversion unit, the insulating substrate being provided with the third busbar, wherein
the insulating substrate includes a plurality of insulating layers,
a first insulating layer of the plurality of insulating layers is positioned on the second busbar,
the first busbar and the third busbar are positioned on the first insulating layer, and
the first busbar, the second busbar, and the third busbar are mutually insulated by the insulating material forming the insulating substrate.

2. The power conversion device according to claim 1, wherein
the first busbar and the second busbar overlap each other at least partially when viewed in a stacking direction of the insulating layers.

3. The power conversion device according to claim 2, wherein
the third busbar and the second busbar overlap each other at least partially when viewed in the stacking direction of the insulating layers.

4. The power conversion device according to claim 1, wherein
each of the first phase terminal, the second phase terminal, and the third phase terminal extends in a stacking direction of the insulating layers and passes through the insulating substrate.

5. The power conversion device according to claim 1, further comprising:
a fourth busbar connected to a first direct-current terminal of the power conversion unit, the insulating substrate being provided with the fourth busbar, and
the fifth busbar connected to a second direct-current terminal of the power conversion unit, the insulating substrate being provided with the fifth busbar, wherein
the first insulating layer is positioned on the second busbar and the fifth busbar,
the first busbar, the third busbar and the fourth busbar are positioned on the first insulating layer, and
the first busbar, the second busbar, the third busbar, the fourth busbar, and the fifth busbar are mutually insulated by the insulating material forming the insulating substrate.

6. The power conversion device according to claim 5, wherein
each of the first phase terminal, the second phase terminal, the third phase terminal, the first direct-current terminal, and the second direct-current terminal extends in a stacking direction of the insulating layers and passes through the insulating substrate.

7. The power conversion device according to claim 5, further comprising:
a snubber capacitor having one end connected to the fourth busbar and another end connected to the fifth busbar.

8. The power conversion device according to claim 1, wherein
the insulating substrate is a printed substrate.
